(19) United States
(12) Patent Application Publication
(10) Pub. No.: US 2017/0073832 A1
(43) Pub. Date: Mar. 16, 2017

(54) DURABLE LOW CURE TEMPERATURE HYDROPHOBIC COATING IN ELECTROPLATING CUP ASSEMBLY

(71) Applicant: Lam Research Corporation, Fremont, CA (US)

(72) Inventors: Aaron Berke, Portland, OR (US); Santosh Kumar, Hillsboro, OR (US); Lee Peng Chua, Beaverton, OR (US); Robert Rash, West Linn, OR (US)

(21) Appl. No.: 15/004,593

(22) Filed: Jan. 22, 2016

Related U.S. Application Data
(60) Provisional application No. 62/217,591, filed on Sep. 11, 2015.

(51) Int. Cl. C25D 17/00; C25D 17/06; C25D 7/12

(52) U.S. Cl. CPC C25D 17/001; C25D 7/12; C25D 17/005; C25D 17/007; C25D 17/004; C25D 17/06; H01L 21/76879

(57) ABSTRACT

Disclosed are electroplating cups for engaging wafers during electroplating, where the electroplating cup can include a ring-shaped cup bottom, an elastomeric seal, and an electrical contact element. The cup bottom may be repeatedly exposed to electroplating solution. The cup bottom can include a non-conductive material upon which a solid lubricant coating can be applied. The solid lubricant coating can be cured at a relatively low temperature, such as less than the melting temperature of the non-conductive material, and can be durable and hydrophobic.

### CROSS-REFERENCE TO RELATED APPLICATIONS

This application claims the benefit of U.S. Provisional Patent Application No. 62/217,591, filed Sep. 11, 2015, and titled “DURABLE LOW CURE TEMPERATURE HYDROPHOBIC COATING FOR REDUCING METAL SENSITIZATION IN ELECTROPLATING APPLICATIONS,” which is incorporated by reference herein in its entirety and for all purposes.

### TECHNICAL FIELD

This disclosure relates to the formation of damascene interconnects for integrated circuits, and electroplating apparatuses which are used during integrated circuit fabrication.

### BACKGROUND

Electroplating is a common technique used in integrated circuit (IC) fabrication to deposit one or more layers of conductive metal. In some fabrication processes it is used to deposit one or more levels of copper interconnects between various substrate features. An apparatus for electroplating typically includes an electroplating cell having a chamber for containing an electrolyte (sometimes called a plating bath) and a substrate holder designed to hold a semiconductor substrate during electroplating. In some designs, the wafer holder has a “clamshell” structure in which the substrate perimeter rests against a ring-shaped structure called a “cup.”

During operation of the electroplating apparatus, a semiconductor substrate is submerged into the plating bath such that at least a plating surface of the substrate is exposed to electrolyte. One or more electrical contacts established with the substrate surface are employed to drive an electrical current through the electroplating cell and deposit metal onto the substrate surface from metal ions available in the electrolyte. Typically, the electrical contact elements are used to form an electrical connection between the substrate and a bus bar acting as a current source.

An issue arising in electroplating is the potentially corrosive properties of the electroplating solution. Therefore, in many electroplating apparatus a lipseal is used at the interface of the clamshell and substrate for the purpose of preventing leakage of electrolyte and its contact with elements of the electroplating apparatus other than the inside of the electroplating cell and the side of the substrate designated for electroplating.

Another issue arising in electroplating is unintentional plating of the cup bottom or other parts of the clamshell structure. Any plating of the cup bottom or other parts of the clamshell structure instead of the substrate can be detrimental to the process performance of electroplating, which can result in non-uniform plating of material across the substrate or even failure in the clamshell structure.

### SUMMARY

A cup bottom of an electroplating cup assembly can include a non-conductive material covered with a solid lubricant coating. The solid lubricant coating can be hydrophobic and durable. The solid lubricant coating can be cured at a temperature below the melting temperature of the non-conductive material, such as a temperature between about 350° F. and about 500° F. The solid lubricant coating can be a mixture of at least two polymers, including a binder polymer and a lubricant polymer. In some implementations, the binder polymer can include a high-performance or engineering polymer, and the lubricant polymer can include a fluoropolymer. The solid lubricant coating on a non-conductive cup bottom can simplify construction of the electroplating cup assembly and can reduce the likelihood of cup bottom plating even in the event of coating failure.

This disclosure pertains to a cup assembly for holding, sealing, and providing electrical power to a wafer during electroplating. The cup assembly includes a cup bottom sized to hold the wafer and comprising a main body portion and a radially inwardly protruding surface, where the main body portion of the cup bottom includes a non-conductive material coated with a solid lubricant coating. The cup assembly also includes an elastomeric seal disposed on the radially inwardly protruding surface, where the elastomeric seal, when pressed against by the wafer, seals against the wafer so as to define a peripheral region of the wafer from which plating solution is substantially excluded during electroplating. The cup assembly further includes an electrical contact element disposed on or proximate the elastomeric seal, where the electrical contact element contacts the wafer in the peripheral region when the elastomeric seal seals against the wafer so that the electrical contact element may provide electrical power to the wafer during electroplating.

In some implementations, the solid lubricant coating is curable at a temperature lower than the melting temperature of the non-conductive material. In some implementations, the solid lubricant coating is curable at a temperature between about 350° F. and about 500° F. In some implementations, the solid lubricant coating includes a binder polymer and a lubricant polymer. The binder polymer includes at least one of polyether sulfone (PES) and polyphenylene sulfide (PPS), and the lubricant polymer includes at least one of polytetrafluoroethylene (PTFE), fluorinated ethylene propylene (FEP), and perfluoroalkoxy (PFA). The binder polymer melts at the cure temperature of the solid lubricant coating, and the lubricant polymer does not melt at the cure temperature of the solid lubricant coating. In some implementations, an entirety or substantial entirety of the cup bottom is made of the non-conductive material. In some implementations, the non-conductive material of the cup bottom includes a polymeric material. The polymeric material includes at least one of polyamide-imide (PAI), polyether ether ketone (PEEK), PPS, and polyethylene terephthalate (PET). In some implementations, the plating solution includes tin and silver ions.

This disclosure also pertains to a method of preparing a cup assembly for holding, sealing, and providing electrical power to a wafer during electroplating. The method includes providing a cup bottom sized to hold the wafer and including a main body portion and a radially inwardly protruding surface, where at least the main body portion comprises a non-conductive material. The method further includes affixing an elastomeric seal on the radially inwardly protruding surface, where the elastomeric seal, when pressed against by the wafer, seals against the wafer so as to define a peripheral region of the wafer from which plating solution is substantially excluded during electroplating. The method further includes coating the non-conductive material of the main body portion with a solid lubricant coating.

In some implementations, the solid lubricant coating includes a binder polymer and a lubricant polymer. The binder polymer includes at least one of PES and PPS, and the lubricant polymer includes at least one of PTFE, FEP, and PFA. In some implementations, the method further includes curing the solid lubricant coating at a temperature below the melting temperature of the non-conductive material. The solid lubricant coating can be cured at a temperature between about 350° F. and about 500° F. In some implementations, the method further includes preparing the solid lubricant coating, where preparing the solid lubricant coating includes dissolving a binder polymer and a lubricant polymer into a solvent. In some implementations, the method further includes pretreating the cup bottom prior to coating the non-conductive material with the solid lubricant coating so as to improve adhesion of the solid lubricant coating to the non-conductive material. In some implementations, the method further includes applying an electrical contact element on or proximate the elastomeric seal, where the electrical contact element contacts the wafer in the peripheral region when the elastomeric seal seals against the wafer so that the electrical contact element may provide electrical power to the wafer during electroplating.

### BRIEF DESCRIPTION OF THE DRAWINGS

FIG. 1A is a perspective view of a wafer holding and positioning apparatus for electrochemically treating semiconductor wafers.

FIG. 1B presents a cross-sectional schematic of an electroplating substrate holder.

FIG. 2 is a cross-sectional schematic of a clamshell assembly having contact rings made with multiple flexible fingers.

FIG. 3 is a flowchart illustrating a method of electroplating a semiconductor substrate.

FIGS. 4A-4D show cross-sectional schematic diagrams of electric field lines at a cup bottom of an electroplating cup that illustrate various stages of metal sensitization over time.

FIG. 5A shows a perspective view of an electroplating cup assembly.

FIG. 5B shows a cross-sectional view of the electroplating cup assembly along line 5B-5B in FIG. 5A.

FIG. 6A shows a perspective view of an electroplating cup assembly with a solid lubricant coating.

FIG. 6B shows a cross-sectional view of the electroplating cup assembly along line 6B-6B in FIG. 6A.

FIG. 7 is a flowchart illustrating a method of forming an electroplating cup assembly coated with a solid lubricant coating.

FIG. 8A shows an image of an electroplating cup assembly made of polyphenylene sulfide (PPS) after electroplating over time.

FIG. 8B shows an image of an electroplating cup made of coated titanium after the coating is scratched and after electroplating over time.

FIG. 8C shows an image of an electroplating cup made of coated PPS after the coating is scratched and after electroplating over time.

### DETAILED DESCRIPTION

In the following description, numerous specific details are set forth in order to provide a thorough understanding of the presented concepts. The presented concepts may be practiced without some or all of these specific details. In other instances, well known process operations have not been described in detail so as to not unnecessarily obscure the described concepts. While some concepts will be described in conjunction with specific embodiments, it will be understood that these embodiments are not intended to be limiting.

In this disclosure, the terms “semiconductor wafer,” “wafer,” “substrate,” “semiconductor substrate”, “wafer substrate,” “work piece” and “partially fabricated integrated circuit” are used interchangeably. One of ordinary skill in the art would understand that the term “partially fabricated integrated circuit” can refer to a silicon wafer during any of many stages of integrated circuit fabrication thereon. Further, the terms “electrolyte,” “plating bath,” “bath,” and “plating solution” are used interchangeably. These terms may generally refer to catholyte (electrolyte present in a cathode chamber or cathode chamber recirculation loop), or to anolyte (electrolyte present in an anode chamber or anode chamber recirculation loop). Additionally, the terms “electroplating cup,” “electroplating cup assembly,” “cup assembly,” and “clamshell assembly” may be used interchangeably. The following detailed description assumes the disclosure is implemented on a wafer. However, the disclosure is not so limited. The wafer may be of various shapes, sizes, and materials. In addition to semiconductor wafers, other work pieces that may take advantage of this disclosure include various articles such as printed circuit boards and the like.

### INTRODUCTION

Advances in semiconductor fabrication and processing have led to the increased use of electroplated tin-silver alloys. Some example applications of tin-silver alloys are disclosed in U.S. patent application Ser. No. 13/305,384, filed Nov. 28, 2011, and titled “ELECTROPLATING APPARATUS AND PROCESS FOR WAFER LEVEL PACKAGING,” which is hereby incorporated by reference in its entirety and for all purposes. Other example applications are disclosed in U.S. Provisional Patent Application No. 61/502,590, filed Jun. 29, 2011, and titled “ELECTRODEPOSITION WITH ISOLATED CATHODE AND REGENERATED ELECTROLYTE,” U.S. Provisional Patent Application No. 61/655,930, filed Jun. 5, 2012, and titled “METHOD OF PROTECTING ANODE FROM PASSIVATION IN ALLOY PLATING SYSTEMS WITH LARGE REDUCTION POTENTIAL DIFFERENCES,” U.S. patent application Ser. No. 13/051,822, filed Mar. 18, 2011, and titled “ELECTROLYTE LOOP WITH PRESSURE REGULATION FOR SEPARATED ANODE CHAMBER OF ELECTROPLATING SYSTEM,” and U.S. patent application Ser. No. 13/853,935, filed Mar. 29, 2013, and titled “CLEANING ELECTROPLATING SUBSTRATE HOLDERS USING REVERSE CURRENT DEPLATING,” each of which is incorporated herein by reference in its entirety and for all purposes. While parts of the present disclosure may refer to tin-silver electroplating chemistries, it will be understood that the disclosure is not so limited and may equally apply to electrodeposition of other metals.

In many of these applications, tin-silver alloys derive their utility, at least in part, from a superior resistance to tin whisker formation, available reasonably stable plating baths and processes, a lower solder melting point, and improved resistance to solder ball connection breaking under shock forces. However, the electroplating of tin-silver alloys onto semiconductor substrates has oftentimes found to be problematic due to the buildup of spurious tin-silver deposits on the electroplating apparatus itself. In particular, it has been found that tin-silver buildup on and around the lipseal and/or cup bottom regions of an electroplating cup—or clamshell assembly—may lead to significant processing difficulties. Such spurious metal accumulation may cause uneven distribution of plating across the substrate and even, in some circumstances, may cause the seal formed between the substrate and lipseal to fail. The result can be reduced process performance or even device failure. For example, the inner portions of the clamshell assembly may become contaminated with potentially harmful and corrosive electroplating solution if the lipseal fails.

### Lipseal and Cup Bottom Design

The information in this section and the following section presents one example of an apparatus including a substrate holder that may incorporate an integrated lipseal as described in more detail in later sections.

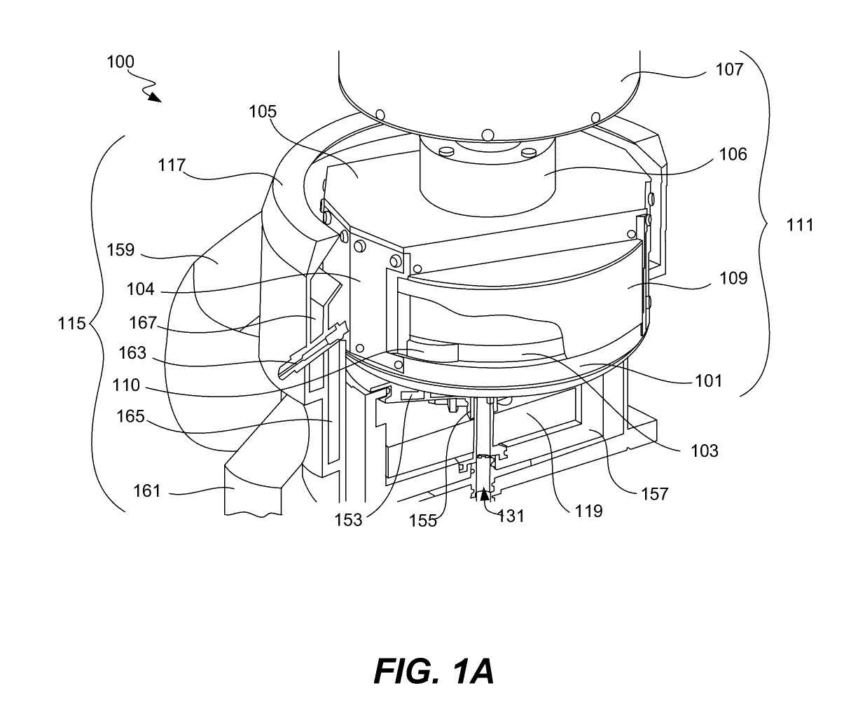

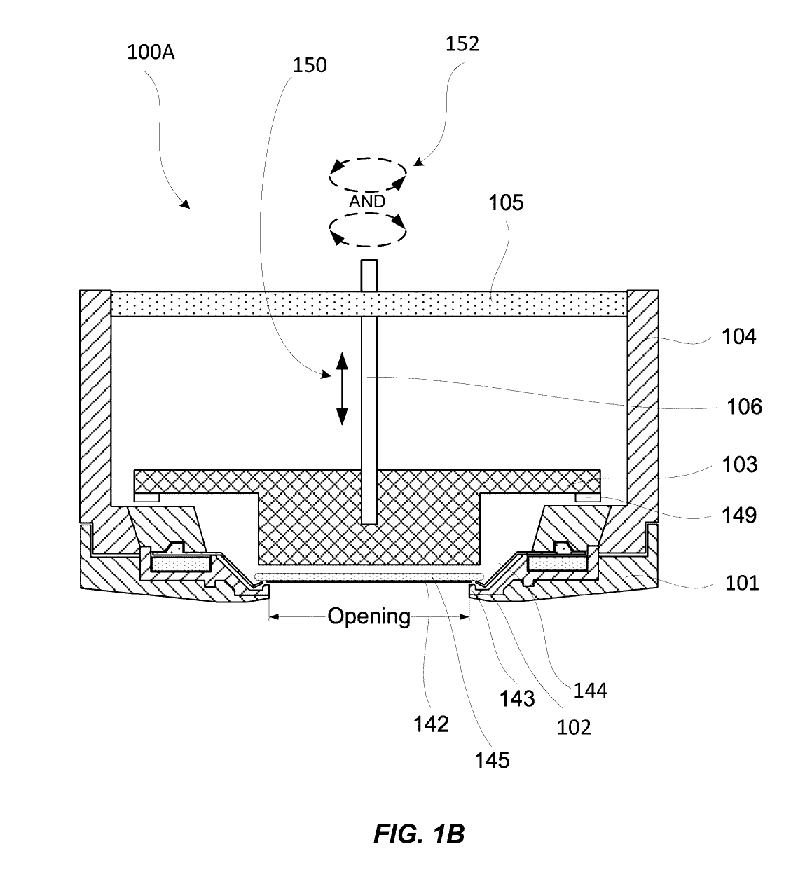

A substrate/wafer holding and positioning component of an electroplating apparatus is presented in FIG. 1A in order to provide some context for the various integrated lipseal and cup assemblies disclosed herein. Specifically, FIG. 1A presents a perspective view of a wafer holding and positioning apparatus 100 for electrochemically treating semiconductor wafers. The apparatus 100 includes wafer-engaging components, which are sometimes referred to as “clamshell components,” or a “clamshell assembly,” or just as a “clamshell.” The clamshell assembly comprises a cup 101 and a cone 103. As will be shown in subsequent figures, the cup 101 holds a wafer and the cone 103 clamps the wafer securely in the cup. During an electroplating process, the semiconductor wafer is supported by the cup 101 and the cone 103. Other cup and cone designs beyond those specifically depicted here can be used. A common feature is that a cup that has an interior region in which the wafer resides and that the cone presses the wafer against the cup to hold it in place.

In the depicted embodiment, the clamshell assembly (which includes the cup 101 and the cone 103) is supported by struts 104, which are connected to a top plate 105. This assembly (101, 103, 104, and 105) is driven by a motor 107 via a spindle 106 connected to the top plate 105. The motor 107 is attached to a mounting bracket (not shown). The spindle 106 transmits torque (from the motor 107) to the clamshell assembly causing rotation of a wafer (not shown in this figure) held therein during plating. An air cylinder (not shown) within the spindle 106 also provides a vertical force for engaging the cup 101 with the cone 103. When the clamshell is disengaged (not shown), a robot with an end effector arm can insert a wafer in between the cup 101 and the cone 103. After a wafer is inserted, the cone 103 is engaged with the cup 101, which immobilizes the wafer within apparatus 100 leaving a working surface on one side of the wafer (but not the other) exposed for contact with the electrolyte solution.

In certain embodiments, the clamshell assembly includes a spray skirt 109 that protects the cone 103 from splashing electrolyte. In the depicted embodiment, the spray skirt 109 includes a vertical circumferential sleeve and a circular cap portion. A spacing member 110 maintains separation between the spray skirt 109 and the cone 103.

For the purposes of this discussion, the assembly including components 101-110 is collectively referred to as a “wafer holder” (or “substrate holder”) 111. Note however, that the concept of a “wafer holder”/“substrate holder” extends generally to various combinations and sub-combinations of components that engage a wafer/substrate and allow its movement and positioning.

A tilting assembly (not shown) may be connected to the wafer holder to permit angled immersion (as opposed to flat horizontal immersion) of the wafer into a plating solution. A drive mechanism and arrangement of plates and pivot joints are used in some embodiments to move wafer the holder 111 along an arced path (not shown) and, as a result, tilt the proximal end of wafer holder 111 (which includes the cup and cone assembly) while it is immersed into the plating solution.

Further, the entire wafer holder 111 is lifted vertically either up or down to immerse the end of wafer holder into a plating solution via an actuator (not shown). Thus, a two-component positioning mechanism provides both vertical movement along a trajectory perpendicular to an electrolyte surface and a tilting movement allowing deviation from a horizontal orientation (i.e., parallel to the electrolyte surface) for the wafer (angled-wafer immersion capability).

Note that the wafer holder 111 is used with a plating cell 115 having a plating chamber 117 which houses an anode chamber 157 and a plating solution. The anode chamber 157 holds an anode 119 (e.g., a copper anode) and may include membranes or other separators designed to maintain different electrolyte chemistries in the anode compartment and a cathode compartment. In the depicted embodiment, a diffuser 153 is employed for directing electrolyte upward toward the rotating wafer in a uniform front. In certain embodiments, the flow diffuser is a high resistance virtual anode (HRVA) plate, which is made of a solid piece of insulating material (e.g. plastic), having a large number (e.g. 4,000-15,000) of one dimensional small holes (0.01 to 0.050 inches in diameter) and connected to the cathode chamber above the plate. The total cross-section area of the holes is less than about 5 percent of the total projected area, and, therefore, introduces substantial flow resistance in the plating cell helping to improve the plating uniformity of the system. Additional description of a high resistance virtual anode plate and a corresponding apparatus for electrochemically treating semiconductor wafers is provided in U.S. Pat. No. 8,308,931, issued on Nov. 13, 2012, which is hereby incorporated by reference herein in its entirety. The plating cell may also include a separate membrane for controlling and creating separate electrolyte flow patterns. In another embodiment, a membrane is employed to define an anode chamber, which contains electrolyte that is substantially free of suppressors, accelerators, or other organic plating additives.

The plating cell 115 may also include plumbing or plumbing contacts for circulating electrolyte through the plating cell—and against the work piece being plated. For example, the plating cell 115 includes an electrolyte inlet tube 131 that extends vertically into the center of anode chamber 157 through a hole in the center of anode 119. In other embodiments, the cell includes an electrolyte inlet manifold that introduces fluid into the cathode chamber below the diffuser/HRVA plate at the peripheral wall of the chamber (not shown). In some cases, the inlet tube 131 includes outlet nozzles on both sides (the anode side and the cathode side) of the membrane 153. This arrangement delivers electrolyte to both the anode chamber and the cathode chamber. In other embodiments, the anode and cathode chamber are separated by a flow resistant membrane 153, and each chamber has a separate flow cycle of separated electrolyte. As shown in the embodiment of FIG. 1A, an inlet nozzle 155 provides electrolyte to the anode-side of membrane 153.

In addition, plating cell 115 includes a rinse drain line 159 and a plating solution return line 161, each connected directly to the plating chamber 117. Also, a rinse nozzle 163 delivers deionized rinse water to clean the wafer and/or cup during normal operation. Plating solution normally fills much of the chamber 117. To mitigate splashing and generation of bubbles, the chamber 117 includes an inner weir 165 for plating solution return and an outer weir 167 for rinse water return. In the depicted embodiment, these weirs are circumferential vertical slots in the wall of the plating chamber 117.

FIG. 1B provides a more detailed cross-sectional view of the substrate holding component 100A (the cup/cone assembly or clamshell assembly) of the electroplating apparatus, including a cross-sectional view of cup 101 and cone 103. Note that the cup/cone assembly 100A depicted in FIG. 1B is not intended to be proportionately accurate. Cup 101, having cup bottom 102, supports the lipseal 143, the contacts 144, buss bar, and other elements, and is itself supported by top plate 105 via struts 104. Generally, a substrate 145 rests on the lipseal 143, just above the contact 144, which is configured to support it. Cup 101 also includes an opening (as labeled in the figure) through which an electroplating bath solution may contact the substrate 145. Note that electroplating takes place on the front side 142 of substrate 145. Thus, the periphery of substrate 145 rests on a bottom inward protrusion of the cup 101 (e.g., “knife-shaped” edge) referred to as the cup bottom 102, or more specifically on lipseal 143 which is positioned on the radially inward edge of the cup bottom 102.

Cone 103 presses down on the back side of substrate 145 to engage it and hold it in place and to seal it against lipseal 143 during submersion of the substrate into the electroplating bath during electroplating. The vertical force from cone 103, which is transferred through substrate 145 compresses lipseal 143 to form the fluid tight seal. Lipseal 143 prevents electrolyte from contacting the backside of substrate 145 (where it could introduce contaminating metal atoms directly into silicon) and from reaching sensitive components of apparatus 100, such as contact fingers that establish electrical connections to edge portions of substrate 145. This electrical connection and associated electrical contacts 144, themselves sealed and protected by the lipseal from becoming wet, is used to supply current to conductive portions of substrate 145 that are exposed to the electrolyte. Overall, lipseal 143 separates unexposed edge portions of substrate 145 from exposed portions of substrate 145. Both portions include conductive surfaces that are in electronic communication with each other.

To load a substrate 145 into cup/cone assembly 100A, cone 103 is lifted from its depicted position via spindle 106 until there is a sufficient gap between the cup 101 and the cone 103 to allow insertion of substrate 145 into the cup/cone assembly 100A. The substrate 145 is then inserted, in some embodiments by a robot arm, and allowed to rest lightly on the lipseal and cup bottom 102 (or on a related component attached to the cup, such as a lipseal 143 as described below). In some embodiments, the cone 103 is lifted from its depicted position until it touches top plate 105. Subsequently, the cone 103 is then lowered to press and engage the substrate against the periphery of cup 101 (the cup bottom 102) or attached lipseal 143 as depicted in FIG. 1B. In some embodiments, the spindle 106 transmits both a vertical force for causing the cone 103 to engage the substrate 145, and also the torque for rotating the cup/cone assembly 100A as well as the substrate 145 being held by the cup/cone assembly. FIG. 1B indicates the directionality of the vertical force and rotational orientation of the torque by solid arrows 150 and dashed arrows 152, respectively. In some embodiments, electroplating of the substrate 145 typically occurs while the substrate 145 is rotating. In certain such embodiments, rotating the substrate 145 during electroplating aids in achieving uniform plating, and aids in removing metallic buildup removal as part of the process described in detail hereafter.

In some embodiments, there may also be an additional seal 149 located between the cup 101 and the cone 103, which engages the surfaces of the cup 101 and cone 103 to generally form a substantially fluid-tight seal when the cone 103 engages the substrate 145. The additional sealing provided by cup/cone seal 149 functions to further protect the backside of the substrate 145. Cup/cone seal 149 may be affixed to either the cup 101, or to the cone 103, engaging the alternative element when the cone 103 engages the substrate 145. Cup/cone seal 149 may be a single component seal or a multi-component seal. Similarly, lipseal 143 may be a single component seal or a multi-component seal. Furthermore, a variety of materials may be used to construct seals 143 and 149, as would be appreciated by one of ordinary skill in the art. For instance, in some embodiments, the lipseal is constructed of an elastomeric material, and in certain such embodiments, a perfluoropolymer.

As stated above, an electroplating clamshell typically includes a lipseal and one or more contact elements to provide sealing and electrical connection functions. A lipseal may be made from an elastomeric material. The lipseal forms a seal with the surface of the semiconductor substrate and excludes the electrolyte from a peripheral region of the substrate. No deposition occurs in this peripheral region and it is not used for forming IC devices, i.e., the peripheral region is not a part of the working surface. Sometimes, this region is also referred to as an edge exclusion area because the electrolyte is excluded from the area. The peripheral region is used for supporting and sealing the substrate during processing, as well as for making electrical connection with the contact elements. Since it is generally desirable to increase the working surface, the peripheral region needs to be as small as possible while maintaining the functions described above. In certain embodiments, the peripheral region is between about 0.5 millimeters and 3 millimeters from the edge of the substrate.

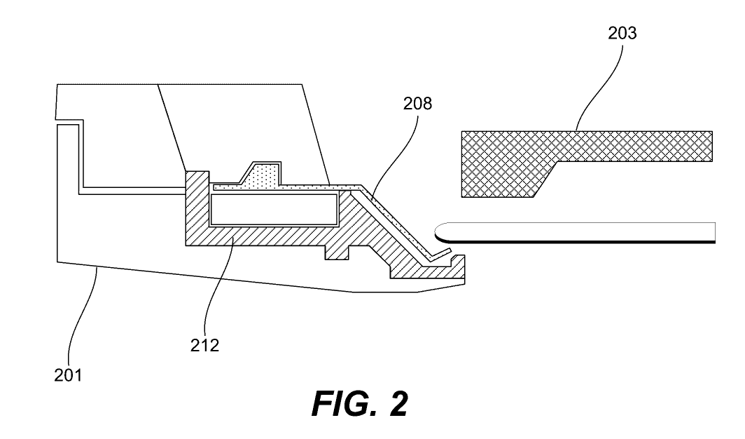

During installation, the lipseal and contact elements are assembled together with other components of the clamshell. One having ordinary skilled in the art can appreciate the difficulty of this operation, particularly, when the peripheral region is small. An overall opening provided by this clamshell is comparable to the size of the substrate (e.g., an opening for accommodating 200 mm wafers, 300 mm wafers, 450 mm wafers, etc.). Furthermore, substrates have their own size tolerances (e.g., +/−0.2 millimeters for a typical 300 mm wafer according to the SEMI specification). A particularly difficult task is alignment of the elastomeric lipseal and contact elements, since both are made from relatively flexible materials. These two components need to have very precise relative location. When a sealing edge of the lipseal and contact elements are positioned too far away from each other, insufficient or no electrical connection may be formed between the contacts and substrate during operation of the clamshell. At the same time, when the sealing edge is positioned too close to the contacts, the contacts may interfere with the seal and cause leakage into the peripheral region. For example, conventional contact rings are often made with multiple flexible “fingers” that are pressed in a spring-like action onto the substrate to establish an electrical connection as shown in the clamshell assembly of FIG. 2 (note cup 201, cone 203, and lipseal 212).

### Method of Sealing a Substrate in a Clamshell

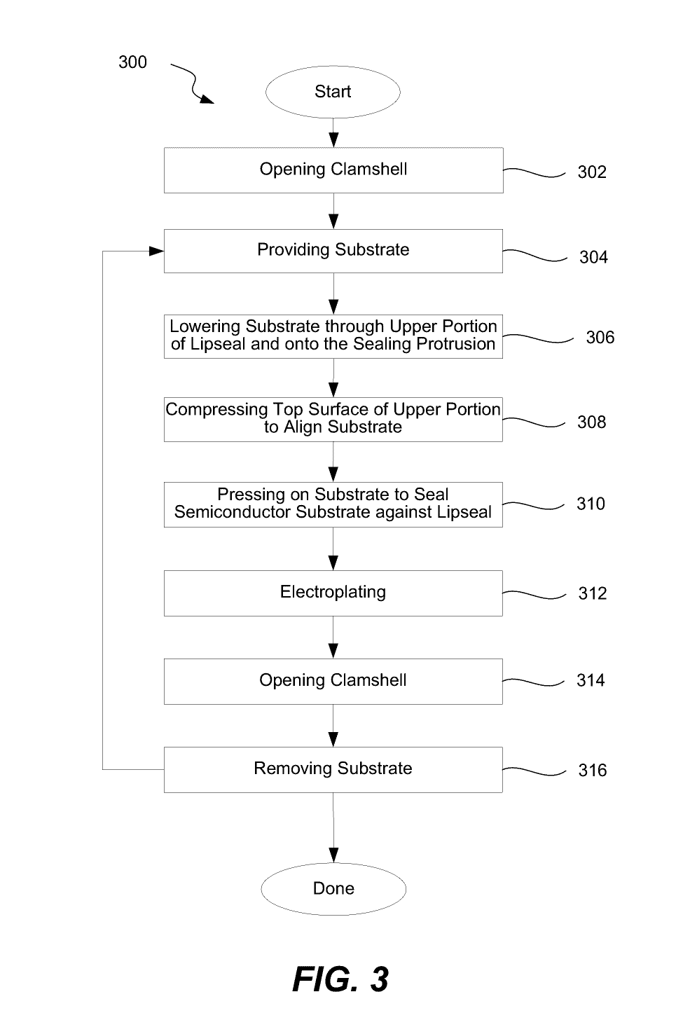

Also disclosed herein are methods of sealing a semiconductor substrate in an electroplating clamshell having an elastomeric lipseal. The flowchart of FIG. 3 is illustrative of some of these methods. For instance, some methods involve opening the clamshell (block 302), providing a substrate to the electroplating clamshell (block 304), lowering the substrate through an upper portion of the lipseal and onto a sealing protrusion of the lipseal (block 306), and compressing a top surface of the upper portion of the lipseal to align the substrate (block 308). In some embodiments, compressing the top surface of the upper portion of the elastomeric lipseal during operation 308 causes an inner side surface of the upper portion to contact the semiconductor substrate and push on the substrate aligning it in the clamshell.

After aligning the semiconductor substrate during operation 308, in some embodiments, the apparatus presses the semiconductor substrate in operation 310 to form a seal between the sealing protrusion and the semiconductor substrate. In certain embodiments, compressing the top surface continues during pressing on the semiconductor substrate. For example, in certain such embodiments, compressing the top surface and pressing on the semiconductor substrate may be performed by two different surfaces of the cone of the clamshell. Thus, a first surface of the cone may press on the top surface to compress it, and a second surface of the cone may press on the substrate to form a seal with the elastomeric lipseal. In other embodiments, compressing the top surface and pressing on the semiconductor substrate are performed independently by two different components of the clamshell. These two pressing components of the clamshell are typically independently movable with respect to one another, thus allowing compression of the top surface to be halted once the substrate is pressed upon and sealed against the lipseal by the other pressing component. Furthermore, the compression level of the top surface may be adjusted based upon the diameter of the semiconductor substrate by independently altering the pressing force exerted upon it by its associated pressing component.

These operations may be part of a larger electroplating process, which is also depicted in the flowchart of FIG. 3 and briefly described below.

Initially, the lipseal and contact area of the clamshell may be clean and dry. The clamshell is opened (block 302) and the substrate is loaded into the clamshell. In certain embodiments, the contact tips sit slightly above the plane of the sealing lip and the substrate is supported, in this case, by the array of contact tips around the substrate periphery. The clamshell is then closed and sealed by moving the cone downward. During this closure operation, the electrical contacts and seals are established according to various embodiments described above. Further, the bottom corners of the contacts may be force down against the elastic lipseal base, which results in additional force between the tips and the front side of the wafer. The sealing lip may be slightly compressed to ensure the seal around the entire perimeter. In some embodiments, when the substrate is initially positioned into the cup only the sealing lip is contact with the front surface. In this example, the electrical contact between the tips and the front surface is established during compression of the sealing lip.

Once the seal and the electrical contact are established, the clamshell carrying the substrate is immersed into the plating bath and is plated in the bath while being held in the clamshell (block 312). A typical composition of a copper plating solution used in this operation includes copper ions at a concentration range of about 0.5-80 g/L, more specifically at about 5-60 g/L, and even more specifically at about 18-55 g/L and sulfuric acid at a concentration of about 0.1-400 g/L. Low-acid copper plating solutions typically contain about 5-10 g/L of sulfuric acid. Medium and high-acid solutions contain about 50-90 g/L and 150-180 g/L sulfuric acid, respectively. The concentration of chloride ions may be about 1-100 mg/L. A number of copper plating organic additives such as Enthone Viaform, Viaform NexT, Viaform Extreme (available from Enthone Corporation in West Haven, Conn.), or other accelerators, suppressors, and levelers known to those of skill in the art can be used. Examples of plating operations are described in more detail in U.S. patent application Ser. No. 11/564,222 filed on Nov. 28, 2006, which is hereby incorporated by reference in its entirety herein. Once the plating is completed and an appropriate amount of material has been deposited on the front surface of the substrate, the substrate is then removed from the plating bath. The substrate and clamshell are then spun to remove most of the residual electrolyte on the clamshell surfaces which has remained there due to surface tension and adhesive forces. The clamshell is then rinsed while continued to be spun to dilute and flush as much of the entrained electrolytic fluid as possible from clamshell and substrate surfaces. The substrate is then spun with rinsing liquid turned off for some time, usually at least about 2 seconds to remove some remaining rinsate. The process may proceed by opening the clamshell (block 314) and removing the processed substrate (block 316). Operational blocks 304 through 316 may be repeated multiple times for new wafer substrates, as indicated in FIG. 3.

### Metal Sensitization

Electroplating and other processes using a clamshell assembly typically involve submerging at least a bottom portion of the clamshell assembly into the electroplating solution. The bottom portion of the clamshell assembly, including a cup bottom of an electroplating cup assembly, is repeatedly exposed to electroplating solution. The cup bottom can include one or more materials, such as a plastic or metal. In some embodiments, the cup bottom of the clamshell assembly can include polyphenylene sulfide (PPS) or coated titanium.

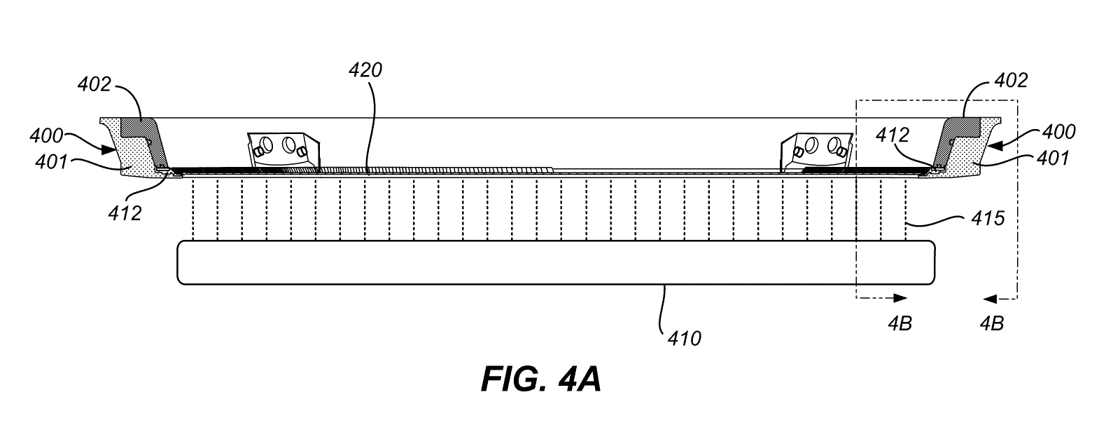

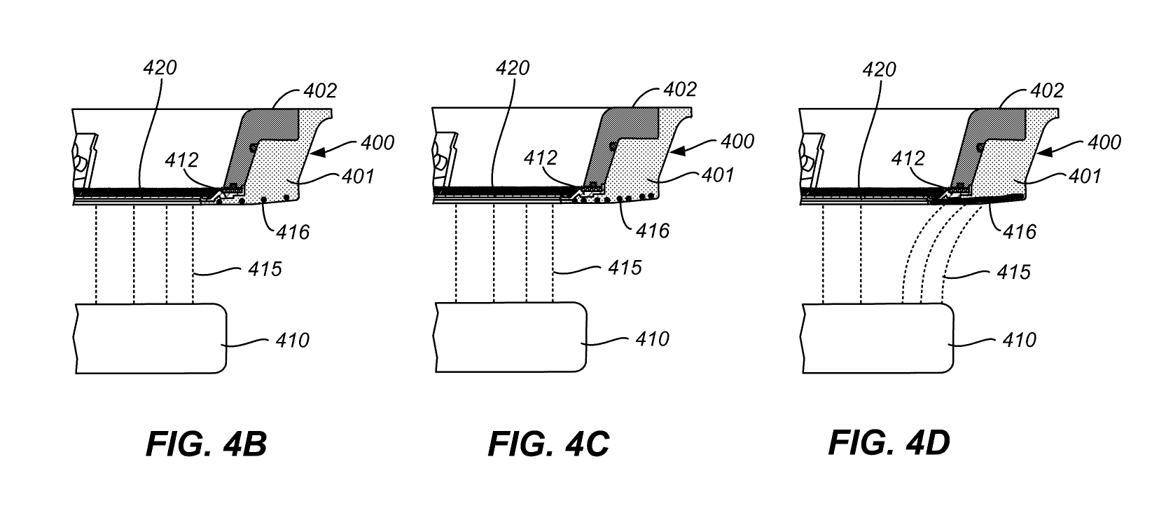

FIGS. 4A-4D show cross-sectional schematic diagrams of electric field lines at a cup bottom of a clamshell assembly that illustrate various stages of metal sensitization over time. FIG. 4A shows the cross-sectional schematic diagram of electric field lines between an anode and a cathode of an electroplating apparatus. The anode can be an electrode such as a tin anode or tin/silver anode, and the cathode can be a semiconductor wafer. The cup bottom in FIG. 4A has not been subject to any metal sensitization, and none of the electric field lines deviate towards the cup bottom. The cup bottom in FIGS. 4B-4D shows the progression of metal sensitization over time at the cup bottom, which results in electric field lines deviating towards the cup bottom in FIG. 4D.

In FIGS. 4A-4D, a cup assembly 400 can include a cup bottom 401, a bus ring 402, a lipseal 412, and contact members (not shown). A wafer 420 can be supported in the cup assembly 400 by the lipseal 412. The lipseal 412 may support, align, and seal the wafer 420 from electrolyte in the cup assembly 400 during plating. The contact members may be disposed over the lipseal 412 and configured to provide electrical power to the wafer 420 when in contact with the wafer 420. The bus ring 402, contact members, and wafer 420 can be electrically energized to generate electric field lines 415 between a cathode at the wafer 420 and an anode 410. The electrically energized wafer 420 produces an electrodeposition reaction at the cathode. However, the cup bottom 401 of the cup assembly 400 is not electrically energized. In some implementations, the cup bottom 401 can be electrically isolated by material properties, such as having the cup bottom 401 made out of electrically insulating material. For example, the cup bottom 401 can be formed from PPS. In some implementations, the cup bottom 401 can be physically isolated from the rest of the electrically energized parts, such as by providing an insulating material/coating between a conductive cup bottom 401 and the electrically energized parts. For example, the cup bottom 401 can include titanium coated with an insulating material, such as fluorinated ethylene propylene (FEP).

Where the cup bottom 401 is made out of an electrically insulating material, such as PPS, the cup bottom 401 may be vulnerable to a phenomenon referred to as “metal sensitization.” Metal sensitization is a process by which metal ions are physically adsorbed to a surface of a material to form catalytic sites, so that the surface of the material over time becomes electrically sensitized. Metal sensitization can be observed in electroless deposition processes, such as in electroless deposition of metal onto plastic. Thus, metal sensitization can promote plating of metals, such as tin or palladium, onto non-conductive materials in electroless plating applications. However, such metal sensitization may not be desirable in electroplating applications where metal sensitization occurs on components (e.g., cup bottom) where plating is not intended.

In some implementations, metal sensitization may occur over time in electroplating applications. For example, tin sensitization can occur for tin-silver electroplating applications, where tin ions physically adsorb onto the surface of a base material to form catalytic sites so that the surface of the base material becomes electrically sensitized. In wafer level packaging, repeated exposure of the cup bottom 401 to tin-silver electroplating chemistry can result in tin sensitization.

In FIG. 4B, the process of tin sensitization can begin where some tin ions 416 from the tin-silver electroplating chemistry physically adsorb and adhere to the surface of the cup bottom 401. While FIGS. 4B-4D illustrate the process of tin sensitization, it will be understood that this phenomenon may occur with other plating chemistries. In FIG. 4C, as the cup bottom 401 is repeatedly exposed to the tin-silver electroplating chemistry, more tin ions 416 may accumulate at the surface of the cup bottom 401 to form a greater surface density. The tin ions 416 become increasingly concentrated over time at the surface of the cup bottom 401. In FIG. 4D, the increased concentration of tin ions 416 cause the cup bottom 401 to be significantly sensitized so that electrical continuity takes place between the cup bottom 401 and the cathode (e.g., the wafer 420). The electrical current gets directed to the wafer 420 and also gets directed to the cup bottom 401 because the cup bottom 401 functions effectively as a conductor. As a result, the electric field lines 415 may deviate towards the cup bottom 401 and electrodeposition of metal takes place on the cup bottom 401.

Cup bottom plating can be detrimental to process performance. Cup bottom plating is stochastic and therefore inherently non-uniform. Non-uniform plating of the cup bottom directly results in a non-uniform deficit of plated metals on the wafer. Non-uniform plating can compromise the integrity and performance of the plated film. This can cause severe degradation and defects in packaging and wafer level packaging (WLP) applications.

### Fluoropolymer Coatings on Conductive Materials

The catalytic sites formed by tin sensitization are inversely proportional to the hydrophobicity of the base material. Increasing the hydrophobicity of the cup bottom reduces tin sensitization, thereby directly reducing the propensity of the cup bottom to electroplate.

In some implementations, at least a portion of the cup bottom can include a conductive material coated with a durable, hydrophobic material. For example, a portion of the cup bottom can include titanium coated with a pure fluoropolymer, such as polytetrafluoroethylene (PTFE) and FEP. Other examples of hydrophobic coatings can include, polyvinylidene fluoride (PVDF), and Parylene.

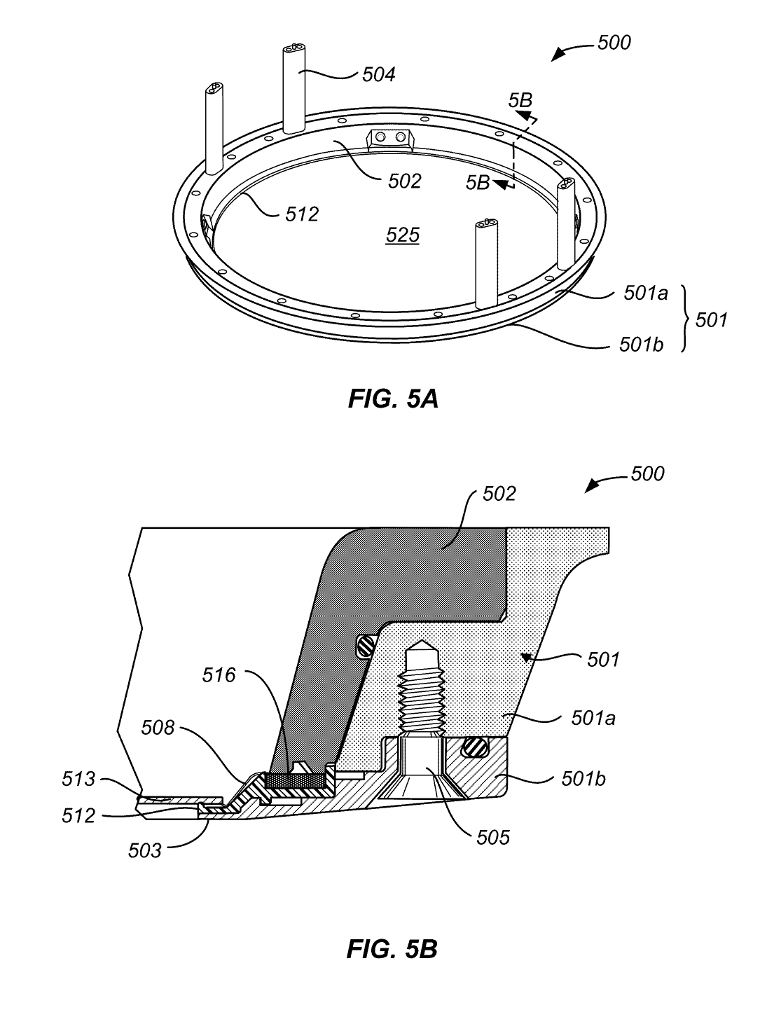

FIG. 5A shows a perspective view of an electroplating cup assembly. As shown in FIG. 5A, an electroplating cup assembly includes several features. The electroplating cup assembly 500 includes a cup bottom 501 that can be ring-shaped to define an opening 525 to allow exposure of a wafer to a plating solution. However, it will be understood that the cup bottom 501 can have other geometries other than ring-shaped. The electroplating cup assembly 500 can further include a bus ring 502 surrounding a main body portion of the cup bottom 501 and radially inwardly facing towards a center of the opening 525. In some implementations, the bus ring 502 may be a continuous thick ring of metal. A plurality of struts 504 may extend from a top surface of the bus ring 502 to support the electroplating cup assembly 500 in a clamshell. The electroplating cup assembly 500 can further include an elastomeric lipseal 512 positioned in the electroplating cup assembly 500 to prevent plating solution from reaching a peripheral region of the wafer. The elastomeric lipseal 512 can be disposed along a radially inwardly protruding surface of the cup bottom 501 and radially inwardly extending towards the center of the opening 525. A portion of the cup bottom 501 can be made of a conductive material 504 coated with a hydrophobic coating. A bottom surface of the cup bottom 501 can include the conductive material 504 as shown in FIG. 5A. In some implementations, the conductive material 504 can be titanium and the hydrophobic coating can be PTFE or FEP.

FIG. 5B shows a cross-sectional view of the electroplating cup assembly 500 along line 5B-5B in FIG. 5A. As shown in FIG. 5B, the cup bottom 501 can include a main body portion 501a and a secondary portion 501b. The main body portion 501a can be positioned over the secondary portion 501b, where the bus ring 502 is disposed on main body portion 501a. The main body portion 501a and the secondary portion 501b can be connected by an attaching mechanism 505, such as a screw. In the secondary portion 501b, the cup bottom 501 includes a portion that radially inwardly protrudes towards the center of the opening 525 defined by the cup bottom 501. A radially inwardly protruding portion can refer to a structure protruding towards a center of a shape, including a shape defined by the cup bottom 501. The radially inwardly protruding portion of the secondary portion 501b provides an exposed surface in the opening 525 upon which additional features of the electroplating cup assembly 500 may be built. This surface may be referred to as a radially inwardly protruding surface 503. The elastomeric lipseal 512 can be disposed on the radially inwardly protruding surface 503 of the secondary portion 501b of the cup bottom 501. The elastomeric lipseal 512 can support a wafer 513 provided in the electroplating cup assembly 500. The elastomeric lipseal 512 can also align and seal the wafer 513 in the electroplating cup assembly 500 to substantially exclude plating solution from reaching a peripheral region of the wafer 513.

The electroplating cup assembly 500 can further include one or more electrical contact elements 508 configured to provide an electrical connection between an external power supply and the wafer 513. The one or more electrical contact elements 508 can be disposed on or proximate the elastomeric lipseal 512. The one or more electrical contact elements 508 may contact the wafer 513 in the peripheral region when the elastomeric lipseal 512 seals against the wafer 513. The one or more electrical contact elements 508 may be configured to provide electrical power to the wafer 513 during electroplating. In some implementations, the one or more electrical contact elements 508 may be electrically connected to a current distribution bus 516 for supplying current to the one or more electrical contact elements 508, which may be electrically connected to the bus ring 502. In some implementations, the one or more electrical contact elements 508 may be integrated with the elastomeric lipseal 512, as described in U.S. application Ser. No. 14/685,526 (attorney docket no. LAMRP162), filed Apr. 13, 2015, and titled “LIPSEALS AND CONTACT ELEMENTS FOR SEMICONDUCTOR ELECTROPLATING APPARATUSES,” and U.S. patent application Ser. No. 13/584,343 (attorney docket no. NOVLP433), filed Aug. 13, 2012, and titled “LIPSEALS AND CONTACT ELEMENTS FOR SEMICONDUCTOR ELECTROPLATING APPARATUSES,” each of which is incorporated herein by reference in its entirety and for all purposes. In some implementations, the elastomeric lipseal 512 may be interlocked with the radially inwardly protruding surface 503 of the cup bottom 501 as described in U.S. patent application Ser. No. 14/936,328 (attorney docket no. LAMRP224), filed Nov. 9, 2015, and titled “INTEGRATED ELASTOMERIC LIPSEAL AND CUP BOTTOM FOR REDUCING WAFER STICKING,” which is incorporated herein by reference in its entirety and for all purposes.

In some implementations, the cup bottom 501 can include at least a portion that is electrically conductive and at least a portion that is electrically insulating. The latter may be the main body portion 501a and the former may be the secondary portion 501b. For example, the cup bottom 501 can include a main body portion 501a that is made of PPS and a secondary portion 501b made of a conductive material, such as titanium. The conductive material can be coated with a hydrophobic material. The hydrophobic coating can be annularly disposed along the surface of the cup bottom 501.

The hydrophobic material can include a fluoropolymer, such as PTFE and its derivatives. Fluoropolymers can provide hydrophobic surface properties with high chemical resistance. However, fluoropolymers can require high melting temperatures to be applied as a coating. In some implementations, fluoropolymers can be cured at a temperature greater than about 700° F., such as between about 700° F. and about 850° F. Appropriate materials that can permit such high melting temperatures for application of the fluoropolymer coating are typically metals, such as titanium. In addition, fluoropolymers may exhibit poor adhesion. Moreover, fluoropolymers may have low hardness. A fluoropolymer coating may be easily scratched and can expose a surface of the metal in the cup bottom. As a result, the exposed metal serves as a conductive site upon which electrodeposition can take place.

While metal coated with a fluoropolymer may generally be effective at preventing cup bottom plating, the cup bottom may still be vulnerable to cup bottom plating once the fluoropolymer coating is scratched or peeled off. The fluoropolymer coating may be easily scratched or peeled during holding or handling of the electroplating cup. An exposed surface of conductive material may lead to cup bottom plating. Because of the electrical conductivity of metals, the high melting temperature of fluoropolymers, the low hardness of fluoropolymers, and the poor adhesion of fluoropolymers to substrates, cup bottom plating may still occur. As discussed above, this can reduce process performance and can even lead to device failure.

### Solid Lubricant Coatings on Non-Conductive Materials

The present disclosure relates to a low cure temperature solid lubricant coating on a non-conductive cup bottom. The solid lubricant coating can provide a durable and hydrophobic surface condition on the cup bottom of an electroplating cup. The solid lubricant coating can be cured at a low temperature, such as between about 350° F. and about 500° F. In some implementations, the solid lubricant coating can be cured at a temperature lower than the melting temperature of the base material of the cup bottom on which the coating is applied. The combination of the solid lubricant coating and the non-conductive cup bottom can simplify the electroplating cup by reducing the number of parts and can improve process performance by reducing the risk of poor electroplating uniformity due to cup bottom plating in the event of a coating failure.

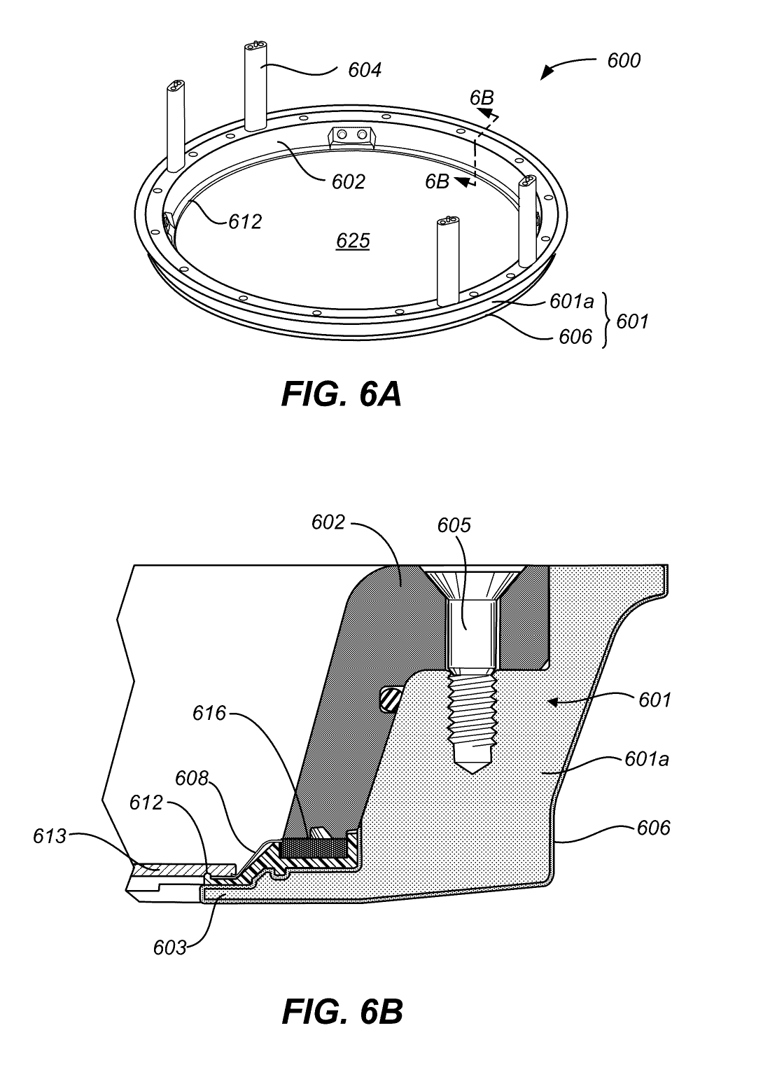

FIG. 6A shows a perspective view of an electroplating cup assembly with a solid lubricant coating. The electroplating cup assembly 600 includes a cup bottom 601 that can be ring-shaped to define an opening 625 to allow exposure of a wafer to a plating solution. However, it will be understood that the cup bottom 601 can have geometries other than ring-shaped. The electroplating cup assembly 600 can further include a bus ring 602 surrounding a main body portion of the cup bottom 601 and radially inwardly facing towards a center of the opening 625. In some implementations, the bus ring 602 may be a continuous thick ring of metal. A plurality of struts 604 may extend from a top surface of the bus ring 602 to support the electroplating cup assembly 600 in a clamshell. The electroplating cup assembly 600 can further include an elastomeric lipseal 612 positioned in the electroplating cup assembly 600 to prevent plating solution from reaching a peripheral region of the wafer. The elastomeric lipseal 612 can be disposed along a radially inwardly protruding surface of the cup bottom 601 and radially inwardly extending towards the center of the opening 625.

FIG. 6B shows a cross-sectional view of the electroplating cup assembly along line 6B-6B in FIG. 6A. As shown in FIG. 6B, the cup bottom 601 can include a main body portion 601a upon which the bus ring 602 is disposed on. The bus ring 602 and the main body portion 601a of the cup bottom 601 can be connected by an attaching mechanism 605, such as a screw. The cup bottom 601 can also include a portion that radially inwardly protrudes towards the center of the opening 625 defined by the cup bottom 601. The radially inwardly protruding portion of the cup bottom 601 provides an exposed surface in the opening 625 upon which additional features of the electroplating cup assembly 600 may be built. This surface may be referred to as a radially inwardly protruding surface 603. The elastomeric lipseal 612 can be disposed on the radially inwardly protruding surface 603 of the cup bottom 601. The elastomeric lipseal 612 can support a wafer 613 provided in the electroplating cup assembly 600. The elastomeric lipseal 612 can also align and seal the wafer 613 in the electroplating cup assembly 600 to substantially exclude plating solution from reaching a peripheral region of the wafer 613. The radially inwardly protruding surface 603 of the cup bottom 601 (and the associated elastomeric lipseal 612) can be sized and shaped to engage with a perimeter of the wafer 613. In various implementations, the wafer 613 is a semiconductor wafer such as a 200-mm, 300-mm, or 450-mm wafer, so the inner diameter of the elastomeric lipseal 612, and typically the supporting cup bottom 601, is very slightly smaller than 200-mm, 300-mm, or 450-mm, such as about 1-5 mm smaller.

The electroplating cup assembly 600 can further include one or more electrical contact elements 608 configured to provide an electrical connection between an external power supply and the wafer 613. The one or more electrical contact elements 608 can be disposed on or proximate the elastomeric lipseal 612. The one or more electrical contact elements 608 may contact the wafer 613 in the peripheral region when the elastomeric lipseal 612 seals against the wafer 613. The one or more electrical contact elements 608 may be configured to provide electrical power to the wafer 613 during electroplating. In some implementations, the one or more electrical contact elements 608 may be electrically connected to a current distribution bus 616 for supplying current to the one or more electrical contact elements 608, which may be electrically connected to the bus ring 602. In some implementations, the one or more electrical contact elements 608 may be integrated with the elastomeric lipseal 612 as described earlier herein. In some implementations, the elastomeric lipseal 612 may be interlocked with the radially inwardly protruding surface 603 of the cup bottom 601 as described earlier herein.

An electroplating cup assembly in FIGS. 6A and 6B can include several components identical or similar to the components of the electroplating cup assembly in FIGS. 5A and 5B. However, in FIGS. 5A and 5B, a secondary portion of the cup bottom is made of metal coated with a fluoropolymer coating instead of a being made of a plastic coated with a solid lubricant coating. In FIGS. 6A and 6B, an entirety or substantial entirety of the cup bottom 601 is made of plastic, such as PPS, and the cup bottom 601 is coated with a solid lubricant coating 606, which can include FEP. The solid lubricant coating 606 can be applied to an exterior surface of a base material of the cup bottom 601 to provide a hydrophobic coating to the cup bottom 601 that can resist metal sensitization. In FIG. 6B, the solid lubricant coating 606 can continue around the radially inwardly protruding surface 603 of the cup bottom 601 and be interposed at an interface between the elastomeric lipseal 612 and the radially inwardly protruding surface 603 of the cup bottom 601.

The properties of the solid lubricant coating 606 may permit the cup bottom 601 to have a non-conductive material rather than a conductive material on which the coating 606 is applied. In particular, where the solid lubricant coating 606 is curable at a temperature below the melting temperature of the non-conductive material, the portion of the cup bottom 601 in which the coating 606 is applied can include the non-conductive material. Because a conductive material may be more subject to undesirable electrodeposition upon exposure (e.g., if the coating 606 is scratched or peeled off), a non-conductive material may be superior because it is less vulnerable to undesirable electrodeposition upon exposure (e.g., if the coating 606 is scratched or peeled off). In some implementations, the base material on which the coating 606 is applied can be plastic rather than metal.

The base material from which the cup bottom 601 is formed is typically a relatively rigid material. In certain implementations, the cup bottom 601 has a rigidity characterized by a Young's modulus of between about 300,000 and 55,000,000 psi, or between about 450,000 and 30,000,000 psi. The base material from which the cup bottom 601 is formed can have a relatively low water absorption. The low water absorption enables the base material to avoid dimensional changes after repeated exposure to electroplating solution. The base material from which the cup bottom 601 is formed can be fairly crystalline, which can provide strength and rigidity to the cup bottom 601. Moreover, the base material from which the cup bottom 601 is formed can be very chemically resistant, even after repeated exposure to electroplating solution.

As described above, the base material from which the cup bottom 601 is formed can be a non-conductive material, such as a polymeric material. In some implementations, the cup bottom 601 is made from a plastic, including but not limited to PPS, polyamide-imide (PAI) such as Torlon®, polyether ether ketone (PEEK), and polyethylene terephthalate (PET). In some implementations, the cup bottom 601 is made from a ceramic material.

The solid lubricant coating 606 can be a mixture of a “binder” polymer and a “lubricant” polymer. Each of the binder polymer and the lubricant polymer can be a powder or other solid form at room temperature. The binder polymer and the lubricant polymer can be mixed and suspended in a solution, such as a glycol. When the solid lubricant coating 606 is cured at an appropriate cure temperature (e.g., between about 350° F. and 500° F.), the binder polymer can melt while the lubricant polymer can remain suspended in solution, thereby producing a two-phase lubricant coating. This leaves solid particles of the lubricant polymer suspended in a matrix of the binder polymer.

The binder polymer can melt at the cure temperature of the solid lubricant coating 606 and serve as a binder and protective matrix for the lubricant polymer. The binder polymer can provide structural integrity to the matrix of the solid lubricant coating 606. The binder polymer can include engineering or high-performance polymers, where such polymers can be fairly crystalline and have high temperature resistance. Examples of binder polymers can include but is not limited to polyether sulfone (PES) and PPS.

The lubricant polymer does not melt at the cure temperature of the solid lubricant coating 606 and can provide hydrophobic surface properties to the solid lubricant coating 606. Because the solid lubricant coating 606 is strongly hydrophobic, the solid lubricant coating 606 is not very wettable, meaning that water does not like to adsorb or adhere to the solid lubricant coating 606. Thus, metal ions such as tin ions are less likely to adsorb onto the solid lubricant coating 606, which reduces the likelihood of metal sensitization. The lubricant polymer can include polymers that are hydrophobic and resistant to chemical attack, such as fluoropolymers and their derivatives. Examples of lubricant polymers can include but is not limited PTFE, FEP, and perfluoroalkoxy (PFA).

An appropriate solid lubricant coating 606 may be supplied by Whitford Corporation of Elverson, Pa., with an example of an appropriate coating being Xylan 8840 or other similar Xylan coatings. In Xylan coatings, the percentage of the solid lubricant coating 606 having a fluoropolymer in its composition may be relatively high. The solid lubricant coating 606 may be cured at a relatively low temperature, such as below the melting temperature of the non-conductive material of the cup bottom 601. The solid lubricant coating 606 may be strongly hydrophobic. In some implementations, the measured contact angle with water is at least 90 degrees. The solid lubricant coating 606 may also be durable. Specifically, the solid lubricant coating 606 may have a greater hardness than a fluoropolymer coating, and may provide better adhesion to the non-conductive material of the cup bottom 601 than a fluoropolymer coating on a conductive material.

In some implementations, a target thickness of the solid lubricant coating 606 can be greater than about 5 μm, such as between about 10 μm and about 100 μm. The solid lubricant coating 606 may be sufficiently hydrophobic to resist metal sensitization upon repeated exposure to plating solution, such as plating solution with tin and silver ions. The solid lubricant coating 606 may also be sufficiently durable and maintain its properties over time. Furthermore, the solid lubricant coating 606 may sufficiently adhere to the non-conductive material of the cup bottom 601 and may be cured at a low temperature so as to minimize degrading the non-conductive material of the cup bottom 601.

Deposition of the solid lubricant coating 606 onto the non-conductive cup bottom 601 can include one or more steps. In some implementations, the non-conductive cup bottom 601 can be pre-conditioned to promote better adhesion of the solid lubricant coating 606. For example, the cup bottom 601 may be sandblasted prior to application of the coating 606. Preparation of the solid lubricant coating 606 may involve dissolving the binder polymer and the lubricant polymer into a solvent, such as glycol. The solution may be applied using techniques known in the art, including having the solution brushed on, spun on, or sprayed on the non-conductive cup bottom 601 to form the solid lubricant coating 606. The solid lubricant coating 606 may be cured at a low temperature, such as between about 350° F. and about 500° F., using techniques known in the art. In some implementations, the solid lubricant coating 606 can be oven cured.

Manufacture of a Cup Bottom with a Solid Lubricant Coating

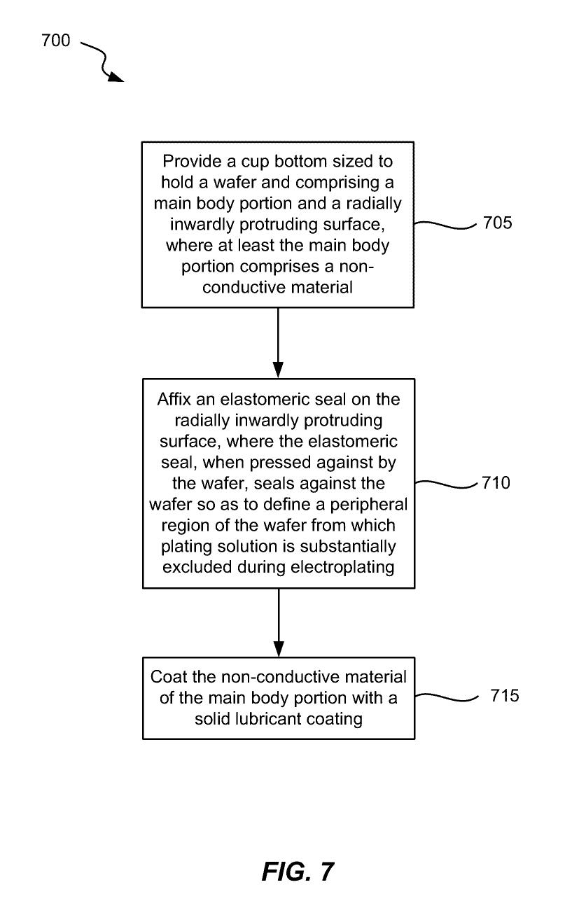

FIG. 7 is a flowchart illustrating a method of forming an electroplating cup assembly coated with a solid lubricant coating. The operations in a process 700 may be performed in different orders and/or with different, fewer, or additional operations.

A process 700 can begin at block 705, where a cup bottom is provided, the cup bottom being sized to hold a wafer and including a main body portion and a radially inwardly protruding surface. At least the main body portion of the cup bottom includes a non-conductive material. In some implementations, the base material that forms the cup bottom can include the non-conductive material. In some implementations, an entirety or substantial entirety of the cup bottom includes the non-conductive material. In some implementations, the non-conductive material can include a polymeric material. Examples of polymeric material include PPS, PAI, PEEK, and PET.

At block 710 of the process 700, an elastomeric seal is affixed on the radially inwardly protruding surface. The elastomeric seal, when pressed against by the wafer, seals against the wafer so as to define a peripheral region of the wafer from which plating solution is substantially excluded. In some implementations, affixing the elastomeric seal can include providing a mold in the shape of an elastomeric lipseal on the radially inwardly protruding surface, delivering a lipseal precursor to the mold, and converting the lipseal precursor to the elastomeric lipseal. In this approach, a chemical precursor (e.g., the lipseal precursor) is placed in the location of the cup bottom surface where the elastomeric lipseal is to reside. The chemical precursor is processed so as to form the desired elastomeric lipseal, such as by polymerization, curing, or other mechanism that converts the chemical precursor into the formed elastomeric lipseal having the desired final structural shape. Examples of curing agents can include cross-linking agents, elevated temperatures, and ultraviolet radiation. In some implementations, affixing the elastomeric seal can be achieved by affixing a pre-formed elastomeric lipseal to the appropriate location on the cup bottom via adhesive, glue, etc. or some other appropriate affixing mechanism.

In some implementations, the process 700 can further include applying an electrical contact element on or proximate the elastomeric seal, where the electrical contact element contacts the wafer in the peripheral region when the elastomeric seal seals against the wafer so that the electrical contact element may provide electrical power to the wafer during electroplating. In some implementations, numerous parallel electrical contact elements may be provided around the wafer and applied to contact the wafer.

In some implementations, the process 700 can further include pretreating the cup bottom prior to coating the non-conductive material of the cup bottom with the solid lubricant coating. Such pretreatment may entail processes that improve adhesion of the solid lubricant coating to the non-conductive material, such as sandblasting.

In some implementations, the process 700 can further include preparing the solid lubricant coating by dissolving a binder polymer and a lubricant polymer into a solvent, such as glycol. The binder polymer and the lubricant polymer can be powders or other solid forms at room temperature. The binder polymer and the lubricant polymer can be mixed and suspended in solution. Examples of binder polymers can include PES and PPS, and examples of lubricant polymers can include PTFE, FEP, and PFA.

At block 715 of the process 700, the non-conductive material of the cup bottom is coated with a solid lubricant coating. The solid lubricant coating may be coated using any suitable deposition or coating technique known in the art, such as having the solid lubricant coating brushed on, spun on, or sprayed on the non-conductive material of the cup bottom. For example, the cup bottom may be cleaned and sand-blasted prior to coating, and then the solid lubricant coating may be prepared and sprayed on the cup bottom before curing. The deposition technique may substantially evenly distribute the solid lubricant coating across the surface of the non-conductive material.

In some implementations, the process 700 further includes curing the solid lubricant coating at a temperature below the melting temperature of the non-conductive material. For example, the temperature for curing the solid lubricant coating can be between about 350° F. and about 500° F. In some implementations, the solid lubricant coating can be cured using any suitable curing technique, such as oven curing. Upon curing, the binder polymer melts to form a binder and protective matrix, whereas the lubricant polymer does not melt and remains suspended in the protective matrix of the binder. Curing the solid lubricant coating produces a two-phase lubricant coating, where solid particles of the lubricant polymer are suspended in a matrix of the binder polymer.

### Results

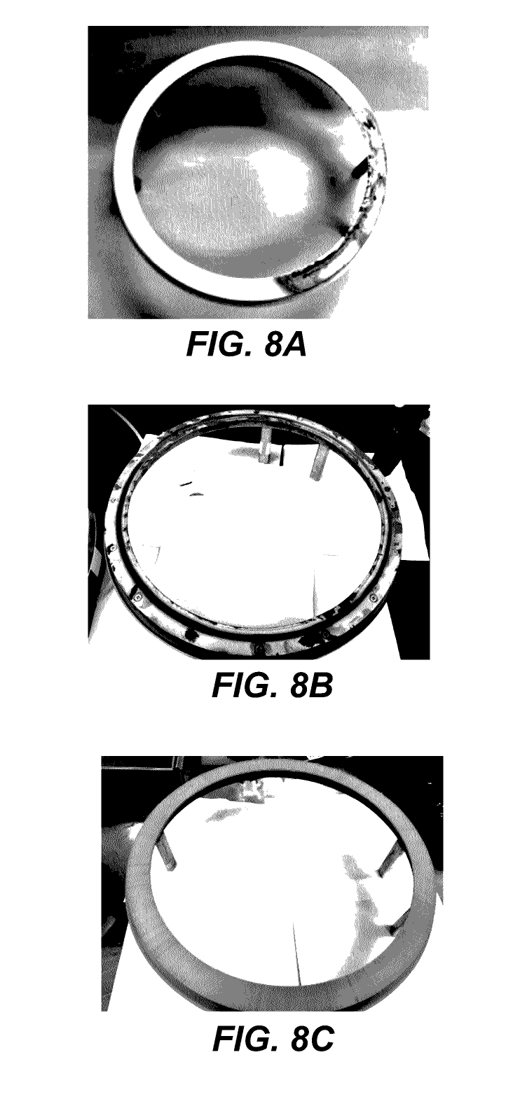

FIG. 8A shows an image of an electroplating cup made of PPS after electroplating over time. When the electroplating cup made of PPS is used to plate several wafers in a tin-silver electroplating bath, portions of the cup bottom of the electroplating cup exhibit plating.

FIG. 8B shows an image of an electroplating cup made of coated titanium after the coating is scratched and after electroplating over time. The coating can include a fluoropolymer, such as FEP. When the coating is scratched and when the electroplating cup is used to plate several wafers in a tin-silver electroplating bath, portions of the cup bottom of the electroplating cup exhibit plating.

FIG. 8C shows an image of an electroplating cup made of coated PPS after the coating is scratched and after electroplating over time. The coating can include a solid lubricant coating as described above. When the coating is scratched and when the electroplating cup is used to plate several wafers in a tin-silver electroplating bath, there is no evidence of plating on the cup bottom.

### System Controllers

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery and circulation of electrolyte, temperature settings (e.g., heating and/or cooling), pressure settings, vacuum settings, electrical power settings, fluid delivery settings, positional and operation settings, wafer transfers into and out of a tool and other transfer tools and/or load locks connected to or interfaced with a specific system. An example of a system can come from the Sabre® family of electroplating systems produced by and made available from Lam Research, Inc. of Fremont, Calif.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller may communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

Lithographic Patterning

The apparatuses/processes described hereinabove may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically comprises some or all of the following steps, each step enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### OTHER EMBODIMENTS

Although illustrative embodiments and applications of this invention are shown and described herein, many variations and modifications are possible which remain within the concept, scope, and spirit of the invention, and these variations would become clear to those of ordinary skill in the art after perusal of this application. Accordingly, the present embodiments are to be considered as illustrative and not restrictive, and the invention is not to be limited to the details given herein, but may be modified within the scope and equivalents of the appended claims.

What is claimed is:

1. A cup assembly for engaging a wafer during electroplating in a clamshell assembly and supplying electrical current to the wafer during electroplating, the cup comprising:
a cup bottom sized to hold the wafer and comprising a main body portion and a radially inwardly protruding surface, wherein at least the main body portion of the cup bottom includes a non-conductive material coated with a solid lubricant coating;
an elastomeric seal disposed on the radially inwardly protruding surface, wherein the elastomeric seal, when pressed against by the wafer, seals against the wafer so as to define a peripheral region of the wafer from which plating solution is substantially excluded during electroplating; and
an electrical contact element disposed on or proximate the elastomeric seal, wherein the electrical contact element contacts the wafer in the peripheral region when the elastomeric seal seals against the wafer so that the electrical contact element may provide electrical power to the wafer during electroplating.

2. The cup assembly of claim 1, wherein the solid lubricant coating is curable at a temperature lower than the melting temperature of the non-conductive material.

3. The cup assembly of claim 1, wherein the solid lubricant coating is curable at a temperature between about 350° F. and about 500° F.

4. The cup assembly of claim 1, wherein the solid lubricant coating is hydrophobic.

5. The cup assembly of claim 1, wherein the solid lubricant coating includes a binder polymer and a lubricant polymer.

6. The cup assembly of claim 5, wherein the binder polymer includes at least one of PES and PPS, and the lubricant polymer includes at least one of PTFE, FEP, and PFA.

7. The cup assembly of claim 5, wherein the binder polymer melts at the cure temperature of the solid lubricant coating, and the lubricant polymer does not melt at the cure temperature of the solid lubricant coating.

8. The cup assembly of claim 1, wherein an entirety or substantial entirety of the cup bottom is made of the non-conductive material.

9. The cup assembly of claim 1, wherein the radially inwardly protruding surface includes the non-conductive material coated with the solid lubricant coating.

10. The cup assembly of claim 1, wherein the non-conductive material of the cup bottom includes a polymeric material.

11. The cup assembly of claim 10, wherein the polymeric material includes at least one of PAI, PEEK, PPS, and PET.

12. The cup assembly of claim 1, wherein the plating solution includes tin and silver ions.
